(19) United States
(12) Patent Application Publication
(10) Pub. No.: US 2025/0174476 A1
(43) Pub. Date: May 29, 2025

(54) Transfer Module, and Substrate Transfer Method in Semiconductor Manufacturing Apparatus

(71) Applicant: Tokyo Electron Limited, Tokyo (JP)

(72) Inventors: Dongwei LI, Yamanashi (JP); Yuki TAKEYOSHI, Yamanashi (JP); Lingxin JIANG, Yamanashi (JP)

(21) Appl. No.: 18/946,836

(22) Filed: Nov. 13, 2024

(30) Foreign Application Priority Data
Nov. 27, 2023 (JP) 2023-199579

(51) Int. Cl. H01L 21/677; H01L 21/67

(52) U.S. Cl. CPC H01L 21/67709; H01L 21/67259; H01L 21/67706; H01L 21/67748

(57) ABSTRACT

A transfer module used in a semiconductor manufacturing apparatus, in which a moving body equipped with a magnet moves in a state of being levitated from a floor by magnetic force to transfer a substrate to a processing module for processing the substrate is provided. The transfer module comprises the moving body, a housing forming a moving space therein where the moving body moves, a power consuming device provided in the moving body, a first coil provided above the moving space, and a second coil provided in the moving body to generate an induced current through a magnetic field formed by the first coil, which is powered, in order to supply power to the power consuming device.

### CROSS-REFERENCE TO RELATED APPLICATIONS

This application claims priority to Japanese Patent Application No. 2023-199579 filed on Nov. 27, 2023, the entire contents of which are incorporated herein by reference.

### TECHNICAL FIELD

The present disclosure relates to a transfer module and a substrate transfer method in a semiconductor manufacturing apparatus.

### BACKGROUND

For example, in a semiconductor manufacturing apparatus that performs processing on a semiconductor wafer (hereinafter also referred to as a “wafer”) as a substrate, the wafer is transferred between a carrier that accommodates the wafer and a processing module that performs processing. When transferring the wafer, various types of transfer mechanisms are used.

The applicant is developing a transfer module used in a semiconductor manufacturing apparatus that transfers a substrate to a processing module using a transfer mechanism that utilizes magnetic levitation.

As a transfer mechanism using magnetic levitation, Japanese Laid-open Patent Publication No. 2022-36757 describes a configuration in which a first magnet is provided on a floor surface of a substrate transfer chamber, while a second magnet is provided in a substrate transfer module, and the substrate transfer module is moved by magnetic levitation using repulsive force of the magnets within the substrate transfer chamber. In addition, it is described that the second magnet is an electromagnet that is powered by a battery provided in the substrate transfer module and that a control signal according to power supply control may be acquired by wireless communication. However, a specific configuration regarding the power supply control is not described.

In addition, Japanese Laid-open Patent Publication No. 2014-531189 describes a technology according to the arrangement of a magnet array in a displacement device which includes a stator having a coil and a movable stage having a magnet array and moves relatively between the stator and the movable stage.

### SUMMARY

The present disclosure provides a technology for improving throughput when supplying power to a power consuming device provided on a moving body in a transfer module which is used in a semiconductor manufacturing apparatus and transfers a substrate to a processing module by the moving body.

The present disclosure relates to a transfer module used in a semiconductor manufacturing apparatus, in which a moving body equipped with a magnet moves in a state of being levitated from a floor by magnetic force to transfer a substrate to a processing module for processing the substrate, the transfer module comprising the moving body, a housing forming a moving space therein where the moving body moves, a power consuming device provided in the moving body, a first coil provided above the moving space, and a second coil provided in the moving body to generate an induced current through a magnetic field formed by the first coil, which is powered, in order to supply power to the power consuming device.

### BRIEF DESCRIPTION OF THE DRAWINGS

FIG. 1 is a plan view illustrating a first embodiment of a semiconductor manufacturing apparatus equipped with a transfer module.

FIG. 2 is a longitudinal side view illustrating a transfer module of the first embodiment.

FIG. 3 is a plan view illustrating a semiconductor manufacturing apparatus of the first embodiment.

FIG. 4 is a plan view illustrating a configuration example of a moving body provided in a transfer module.

FIG. 5 is a side view illustrating a configuration example of a moving body.

FIG. 6 is a perspective view illustrating a driving coil of a moving body.

FIG. 7 is a longitudinal side view illustrating a configuration example of a driving coil and a magnet provided in a moving body.

FIG. 8 is a block diagram illustrating an electrical configuration of a system that performs power supply.

FIG. 9 is a longitudinal side view illustrating an operation of the transfer module of the first embodiment.

FIG. 10 is a plan view illustrating a second embodiment of a semiconductor manufacturing apparatus equipped with a transfer module.

FIG. 11 is a longitudinal side view illustrating a transfer module of the second embodiment.

FIG. 12 is a plan view illustrating an operation of the transfer module of the second embodiment.

FIG. 13 is a plan view illustrating an operation of the transfer module of the second embodiment.

### DETAILED DESCRIPTION

### <Semiconductor Manufacturing Apparatus>

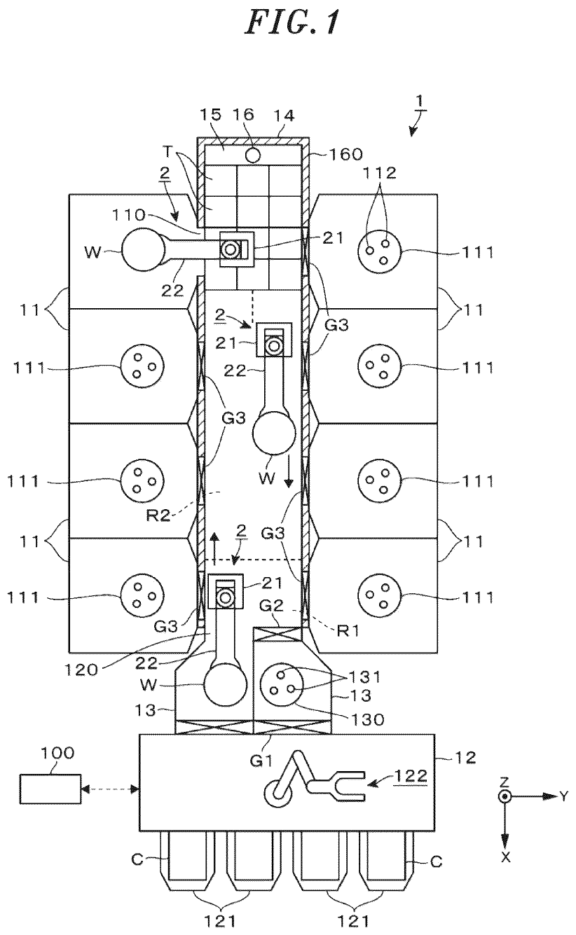

Hereinafter, a transfer module according to a first embodiment of the present disclosure is described. FIG. 1 is a plan view illustrating a semiconductor manufacturing apparatus 1 equipped with a transfer module.

FIG. 1 illustrates a multi-chamber type semiconductor manufacturing apparatus 1 equipped with a plurality of processing modules 11 for processing wafers W. As shown in this drawing, in the semiconductor manufacturing apparatus 1, an atmospheric transfer chamber 12, a load lock module 13, and a transfer module 14 are arranged in a front-back direction. In addition, a plurality of processing modules 11 are provided in a left-right direction of the transfer module 14. Hereinafter, in the semiconductor manufacturing apparatus 1, the front-back direction is referred to as an “X direction”, the left-right direction that intersects the front-back direction horizontally is referred to as a “Y direction”, and in the front-back direction, the atmospheric transfer chamber 12 side is described as an immediately front side and the transfer module 14 side is described as an inner side.

Right in front of the atmospheric transfer chamber 12, a load port 121 is provided on which a carrier C for receiving a wafer W to be processed is mounted. As the carrier C, for example, a front opening unified pod (FOUP) may be used.

In addition, the load lock module 13 is connected to the inner side of the atmospheric transfer chamber 12. In this example, a plurality of load lock modules 13, for example, two load lock modules, are provided in the left-right direction.

The atmospheric transfer chamber 12 is provided with an atmospheric pressure (normal pressure) atmosphere, includes a transfer mechanism 122 provided therein, and is configured to perform transfer of the wafer W between the carrier C and the load lock module 13.

The load lock module 13 is configured to be able to switch between an atmospheric pressure atmosphere and a vacuum atmosphere and is equipped with a stage 130 for transfer on which the wafer W is mounted and a lifting pin 131. The lifting pin 131 is provided to be retractable with respect to the stage 130.

The processing module 11 is a module for performing processing of the wafer W, and in this example, the processing module 11 is decompressed to a vacuum atmosphere by a vacuum exhaust mechanism (not shown) and is configured to perform processing on the wafer W under the vacuum atmosphere. A mounting table 111 and a lifting pin 112 are provided inside each processing module 11, and the lifting pin 112 is provided to be retractable with respect to the mounting table 111. The wafer W is subjected to a predetermined processing while mounted on the mounting table 111, and examples of the processing performed on the wafer W include etching processing, film formation processing, annealing processing, and ashing processing.

### First Embodiment of Transfer Module

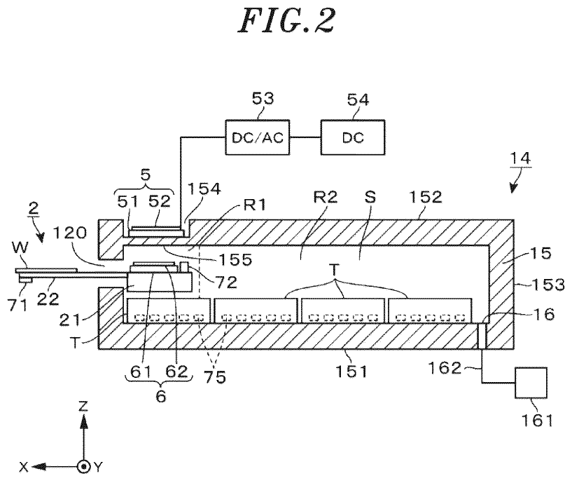

As shown in FIG. 1, the transfer module 14 includes a housing 15 that is long in the front-back direction and is rectangular on a plane. As shown in FIGS. 1 and 2, the housing 15 has a floor 151, a ceiling wall 152, and a sidewall 153, and is formed of metal, for example, aluminum (Al).

Right in front of the housing 15, the load lock module 13 is connected from the side. On the left and right sides of the housing 15, a plurality of processing modules, for example, four processing modules 11, are connected from the side. In addition, a moving body 2 is provided inside the housing 15 to perform transfer of the wafer W between the load lock module 13 and each processing module 11.

The moving body 2 is configured to move in a state in which a main body portion 21 equipped with a magnet 4 is levitated from the floor 151 by magnetic force, and the inside of the transfer module 14 is formed as a moving space S in which the moving body 2 moves.

For example, an exhaust port 16 is formed in the floor 151 of the housing 15, and the exhaust port 16 is connected to an exhaust mechanism 161 including a valve or a vacuum pump through an exhaust path 162. Also, exhausted by the exhaust mechanism 161, the moving space S within the housing 15 is decompressed to a vacuum atmosphere. In addition, the exhaust port 16 that exhausts the moving space S is not limited to being formed in the floor 151 of the housing 15 and may be formed in the sidewall 153 of the housing 15.

A first transfer port 110 opened to transfer the wafer W between the transfer module 14 and the processing module 11 and a second transfer port 120 opened to transfer the wafer W between the transfer module 14 and the load lock module 13 are formed in the sidewall 153 of the housing 15. In FIG. 1, reference numerals G1, G2, and G3 are gate valves for opening and closing the transfer ports of the wafer W, such as the first transfer port 110, the second transfer port 120, etc., and reference numeral G3 corresponds to a first valve that opens and closes the first transfer port 110, and reference numeral G2 corresponds to a second valve that opens and closes the second transfer port 120. The gate valves G1 to G3 are closed except when necessary for the transfer of the wafer W between the modules and separate the atmosphere of the transfer module 14 and the atmosphere of the module connected to the transfer module 14.

In the transfer module 14, the transfer of the wafer W is performed using a plurality of moving bodies 2. For example, a length of the housing 15 of the transfer module 14 in a shorter-side direction is such that a plurality of moving bodies 2, for example, two pairs, holding the wafer W, may be arranged left and right and misaligned.

In addition, the transfer module 14 is configured to wirelessly supply power to the power consuming device provided in the moving body 2. The power supply is performed by electromagnetic induction, and a first coil 5, which is a coil for power supply, is provided on the housing 15 side, and a second coil 6, which is a coil for power reception, is provided on the moving body 2 side. The second coil 6 is configured to generate an induced current through a magnetic field formed by the first coil 5.

The first coil 5 is provided above a region where a dwell time of the moving body 2 per unit time is long in the moving space S. Here, in the moving space S, regions in which the positions in a lateral direction (horizontal direction) are different from each other and the dwell times of the moving body 2 per unit time are different from each other are referred to as a first region R1 and a second region R2. The first region R1 is a region where the dwell time is longer than that of the second region R2. The first coil 5 is provided above the first region R1.

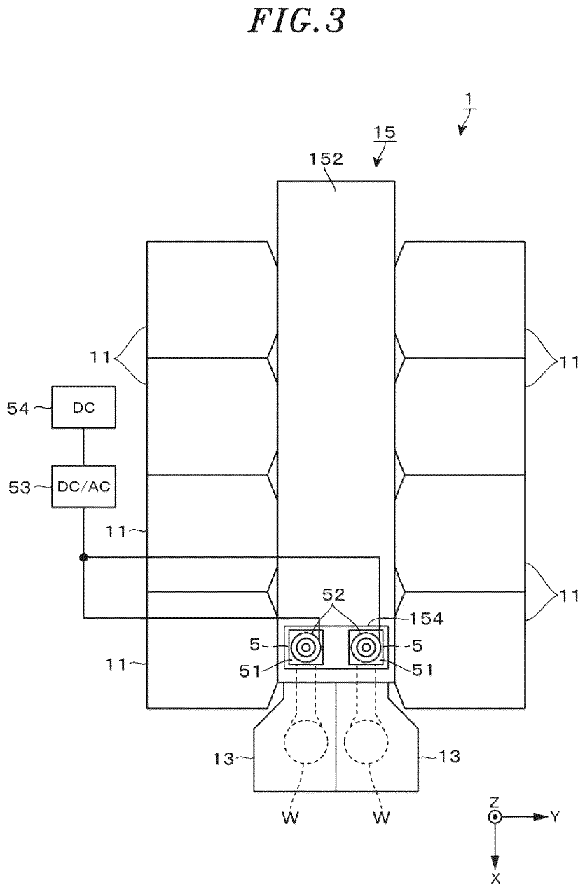

In this example, the first region R1 is set as a region including a transfer position at which the moving body 2 transfers the wafer W between the moving body 2 and the load lock module 13, and the second region R2 is a region other than the corresponding region. In FIG. 1 and FIG. 2, the moving body 2 at the aforementioned transfer position is shown as the solid line, and in FIG. 3, the moving body 2 is shown as the broken line. When transferring the wafer W between the carrier C and one or more processing modules 11, the moving body 2 accesses the load lock module 13 at each of the time of loading and unloading to the transfer module 14. Therefore, a dwell time of the load lock module 13 at the transfer position becomes longer than a dwell time at other positions in the transfer space S. Therefore, the corresponding transfer position is set as the first region R1, and the first coil 5 is disposed such that power is supplied during the dwell at the transfer position.

For example, the first coil 5 is provided above the first region R1, for example, at an upper position close to the load lock module 13 on the outside of the ceiling wall 151 of the housing 15. Specifically, a concave portion 154 that is open upward is formed in the ceiling wall 151 of the housing 15 corresponding to the first region R1, and the first coil 5 is accommodated in the concave portion 154.

As shown in FIGS. 2 and 3, for example, when the moving body 2 is at the transfer position, the first coil 5 is located to face the second coil 6 of the moving body 2 described below through the housing 15 (a lower wall of the concave portion 154) and is disposed such that winding axes thereof are aligned when viewed on a plane. By such arrangement, the second coil 6 enters a region in which magnetic field formed by the first coil 6 is relatively strong, and an induced current is generated in the second coil 6 as described below. The first coil 5 is prepared for each load lock module 13, and two first coils 5 are arranged to be parallel to each other in the left-right direction within the concave portion 154.

The first coil 5 is formed by winding a coil wire 52 in a spiral shape on an upper surface of a base member 51 formed of an insulator. For example, in the example illustrated in FIG. 3, the base member 51 is configured as a rectangle when viewed on a plane, and the coil wire 52 is depicted as a concentric circle for convenience of illustration. The first coil 5 formed in this manner is open in an up-down direction (a Z direction), and the coil wire 52 is connected to a power supply unit 54 that supplies direct current (DC) power via a DC/AC conversion circuit 53.

The first coil 5 and the second coil 6 of the moving body 2 at the transfer position face each other via a lower wall 155 of the concave portion 154 in which the first coil 5 is provided. A thickness of the lower wall 155 is set to a size that does not interfere with power supply by electromagnetic induction using the first coil 5 and the second coil 6 and also to a size that prevents deformation of the housing due to a pressure difference inside and outside the transfer module 14.

### <Moving Body>

Subsequently, the moving body 2 is described. The moving body 2 is configured to be movable inside the transfer module 14 by magnetic levitation. In addition, the moving body 2 is equipped with a function that may not only perform the transfer of the wafer W, but also perform wireless power supply to the power consuming device provided in the moving body 2. Hereinafter, the configuration of the device related to the transfer of the wafer W and wireless power supply using the moving body 2 is described.

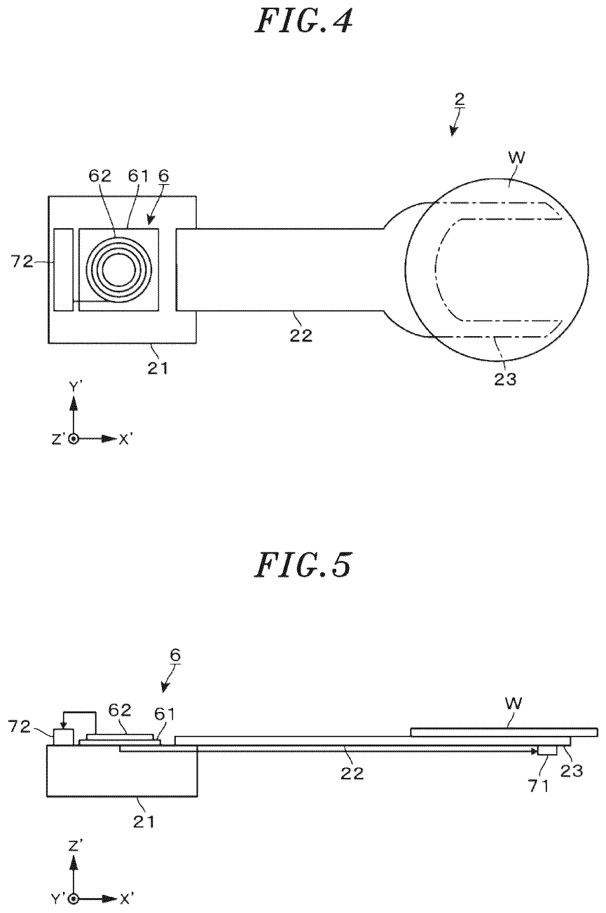

FIG. 4 is a plan view of the moving body 2, and FIG. 5 illustrates a side view thereof, respectively.

As shown in the drawing, the moving body 2 includes a main body portion 21 and a fork 22 that is provided to extend in a lateral direction (a horizontal direction) with the main body portion 21 as a base. In addition, a substrate holding portion 23 for horizontally holding the wafer W to be transferred is formed at the tip of the fork 22. The substrate holding portion 23 is configured to surround three lifting pins 131 and 112 provided in, for example, the load lock module 13 or the processing module 11 from the side. In FIG. 4 and FIG. 5, a configuration in which a base side of the fork 22 is connected to an upper surface of the main body portion 21, but the connection between the fork 22 and the main body portion 21 is not limited to this configuration.

The fork 22 is configured with a length that allows the transfer of the wafer W between the mounting table 111 within the processing module 11 and the stage 130 within the load lock module 13 through the first transfer port 110 and the second transfer port 120, for example, while the main body portion 21 is located in the transfer module 14. As illustrated in FIGS. 4 to 7, etc., the moving body 2 is described using the coordinate system X′, Y′, and Z′ set in the module 2. In this coordinate system, a protruding direction of the fork 22 is a front-rear direction (an X′ direction), and a front end side of the fork 22 in the front-rear direction is the front. In addition, a direction that intersects the front-rear direction horizontally is a left-right direction (a Y′ direction). In addition, in drawings other than FIGS. 4 and 5, for convenience of illustration, a base end of the fork 22 is configured to be connected to the sidewall on the front side of the main body portion 21.

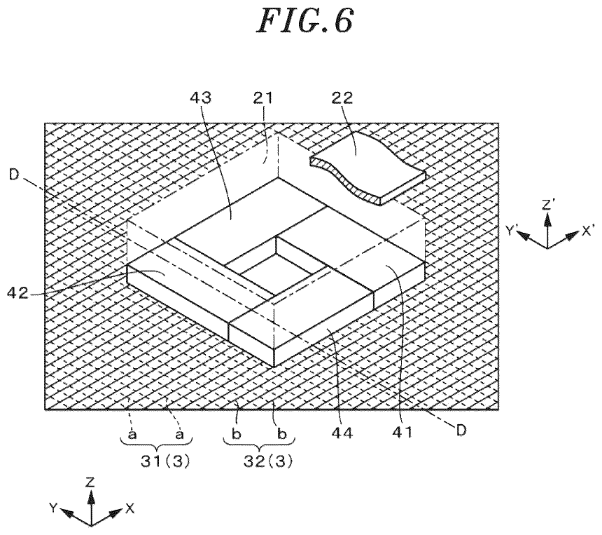

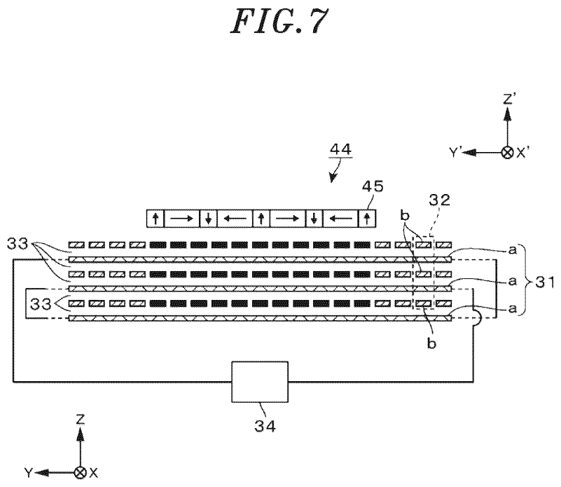

The main body portion 21 is configured to have, for example, a square shape when viewed on a plane, Also, as shown in FIG. 6, a plurality of magnets, four magnets 4 (41, 42, 43, and 44) in this example, are provided in this example. The magnets 4 are configured so that repulsive force acts between them and a magnetic field formed by a driving coil 3 provided on the floor 151 of the housing 15 described below. These four magnets 4 are formed to have, for example, a rectangular shape when viewed from the same plane, are fitted within the square main body portion 21, and are arranged along the four sides of an outer circumference of the main body portion 21.

Each magnet 4 is configured by a plurality of permanent magnets 45, for example, nine permanent magnets, arranged to have a Halbach arrangement, respectively. In addition, FIG. 7 schematically illustrates nine permanent magnets 45 and a magnetization direction thereof, for example, a representative magnet 44. As shown in FIG. 6, when the moving body 2 is disposed so that the fork 22 faces the forward side in the X′ direction, the magnets 43 and 44 arrange nine permanent magnets 45 in a parallel manner in the Y′ direction, and a magnetization direction of these permanent magnets 45 are oriented in a direction orthogonal to the X′ direction. Similarly, the magnets 41 and 42 arrange nine permanent magnets 45 in a parallel manner in the X′ direction, and a magnetization direction of these permanent magnets 45 are oriented in a direction orthogonal to the Y′ direction.

In addition, the moving body 2 is provided with a power consuming device, for example, on a lower surface of a front end side of the substrate holding portion 23. As the power consuming device, for example, a sensor 71 located in the processing module 11 and detecting a state within the processing module 11 when the wafer W is transferred between the processing module 11 and the moving body 2 may be used. Examples of the sensor 71 may include a distance sensor that detects a distance to a component provided in the processing module 11, a temperature sensor that detects a temperature within the processing module 11, and the like. In addition, in the moving body 2, for example, a transmitter that wirelessly transmits detection data by the sensor 71 to a controller 100 described below is provided in the main body portion 21. A storage battery 72 described below supplies power to the sensor 71 and also supplies power to the transmitter. The transmitter also corresponds to a power consuming device.

In a case in which a distance sensor is provided as the sensor 71, for example, when the moving body 2 performs a predetermined movement while the substrate holding portion 23 enters the processing module 11, a plurality of positions of the circumference of the mounting table 111 are detected. Also, the controller 100 calculates a center position of the mounting table 111 from each detection position and performs position control of the moving body 2 so that the fork 22 is disposed at a predetermined position with respect to the center position when viewed on a plane. As a result, the center of the wafer W supported by the substrate holding portion 23 is aligned with respect to the center position of the mounting table 111, and the corresponding wafer W is transferred to the mounting table 111. In a case in which a temperature sensor is provided as the sensor 71, for example, a temperature when the fork 22 enters the processing module 11 is detected, and whether there is an abnormality in the operation of the processing module 11 may be determined by determining whether the temperature is normal by the controller 100.

In addition, the power consuming device may be a camera for imaging the state inside the processing module 11 and a lighting device that projects light into an imaging range of the camera. By imaging, the controller 100 may perform position control of the moving body 2 by identifying the center position of the mounting table 111 mentioned above or perform an abnormality determination, such as the presence or absence of contamination inside the module. In addition, the power consuming device is not limited to a sensor located inside the processing module 11 and detecting the state inside the processing module 11, and an acceleration sensor or the like that detects a speed of the moving body 2 may be provided. As the power consuming device, a plurality of the examples may be combined to be provided.

In addition, the moving body 2 is equipped with the second coil 6 and the battery 72 for supplying power to the sensor 71. The second coil 6 and the battery 72 are arranged side by side in the front-back direction on the upper surface of the main body portion 21 so that the second coil 6 is on the substrate holding portion 23 side, as shown in FIGS. 4 and 5, for example. However, the second coil 6 and the battery 72 may be provided on an upper surface of the fork 22 or the sidewall of the main body portion 21, rather than on the upper surface of the main body portion 21. The second coil 6 may be electrically connected to the battery 72, and the battery 72 may be electrically connected to the sensor 71.

As described above, the second coil 6 generates an induced current through a magnetic field formed by the first coil 5, Also, like the first coil 5, a coil wire 62 is wound in a spiral shape on the upper surface of a base member 61 formed by an insulator. The second coil 6 formed in this manner is open in the up-down direction (the Z′ direction). In the example illustrated in FIG. 4, the base member 61 is configured to have a rectangular shape when viewed on a plane, and for convenience of illustration, the coil wire 62 is depicted as a concentric circle. The battery 72 is charged using an induced current generated by the second coil 6.

The base member 51 or coil wire 52 constituting the first coil 5 is set to a size that does not interfere with the transfer of the wafer W. Meanwhile, the base member 61 or coil wire 62 constituting the second coil 6 may have, for example, the same size as the first coil 5 when viewed on a plane or may be formed to be larger than the first coil 5.

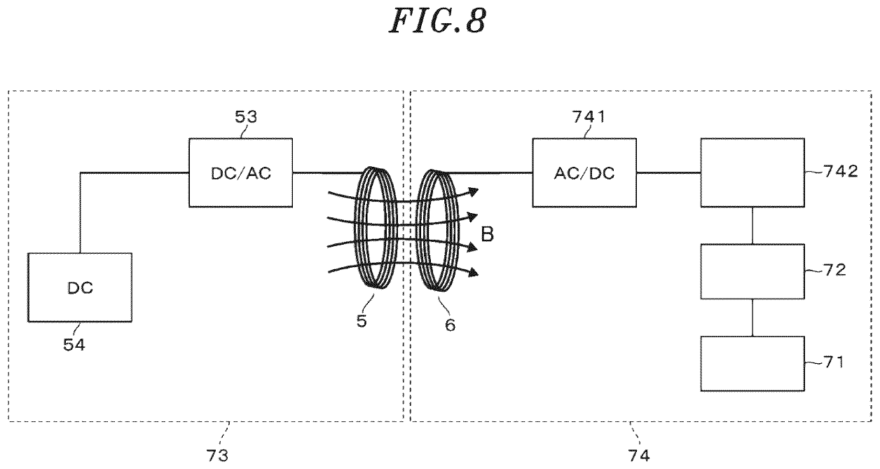

FIG. 8 is a block diagram illustrating an electrical configuration of a system that supplies power. This drawing illustrates a configuration of each of a power supply mechanism 73 on the first coil 5 side and a power receiving mechanism 74 on the second coil 6 side.

The power supply mechanism 73 on the first coil 5 side is equipped with the first coil 5, the DC/AC conversion circuit 53, and the power supply unit 54. In this manner, DC power supplied from the power supply unit 54 is converted into AC power by the DC/AC conversion circuit 53 and is constantly supplied to each first coil 5, for example, during the operation of the semiconductor manufacturing apparatus 1. However, the controller 100 may switch whether to supply power to each first coil 5 via a switch (not shown) and supply power to the first coil 5 above the corresponding transfer position only when the moving body 2 is located at the transfer position with respect to the load lock module 13.

Meanwhile, the power receiving mechanism 74 on the moving body 2 side is equipped with the second coil 6, an AC/DC conversion circuit 741, a voltage regulator 742, and the storage battery 72. The AC power generated in the second coil 6 is converted into DC power by the AC/DC conversion circuit 741, and the DC power is voltage-regulated by the voltage regulator 742 and supplied to the battery 72. In addition, FIG. 8 illustrates magnetic flux B penetrating through an opening of the second coil 6 when the first coil 5 and the second coil 6 are opposed to each other and AC power is supplied to the first coil 5. Directions of the current are different due to the supply of AC power, and accordingly, the direction of the magnetic flux B changes. In addition, in the second coil 6, an electromotive force is generated according to the change in the magnetic flux B penetrating through the opening, and an induced current is generated in the second coil 6.

### <Driving Coil>

Subsequently, the driving coil 3 for driving the moving body 2 is described with reference to FIGS. 1, 2, 6, and 7. On the floor 151 of the housing 15, as schematically illustrated in a portion of FIG. 1 and FIG. 2, a plurality of rectangular tile units T viewed on a plane are arranged lengthwise and crosswise, and a plurality of driving coils 3 are provided inside each tile unit T. A region in which the driving coils 3 are installed is the entire moving region of the moving body 2, from the transfer position of the wafer W with the load lock module 13 to just in front of the processing module 11.

The driving coil 3 is described with reference to FIGS. 6 and 7. FIG. 7 is a longitudinal side view taken along line D-D in FIG. 6. The driving coil 3 of this example is provided with a linear A coil 31 indicated by the broken line in the drawing and a linear Y coil 32 indicated by the solid line. The A coil 31 is provided in plurality and the plurality of A coils 31 are arranged and spaced apart from each other in the X direction and extend in the Y direction. In addition, the B coil 32 is provided in plurality and the plurality of B coils 32 are arranged and spaced apart from each other in the Y direction, and extend in the X direction.

Each of the A coil 31 and B coil 32 includes coil wires a and b, and as schematically illustrated in FIG. 7, these coil wires a and b are alternately stacked, for example, and the coil wires a and b stacked above and below are insulated from each other by an insulating layer 33. The stack structure of the coil wire a, coil wire b, and insulating layer 33 are configured by, for example, a printed circuit board. In addition, the number of layers of coil wires a and b shown in FIG. 7 is an example and may be appropriately changed as needed.

As shown in FIG. 7, the coil wire a is electrically connected to the coil wire a disposed on a upper or lower layer side to have a spiral shape when viewed in the Y-Z longitudinal section. Also, by connecting both ends thereof to the power supply unit 34, the A coil 31 is formed.

Similarly, the coil wire b is electrically connected to the coil wire b disposed on an upper or lower layer side to have a spiral shape when viewed in the X-Z longitudinal section. Also, by connecting both ends thereof to the power supply unit 34, the Y coil 32 is formed. In addition, FIG. 6 illustrates the uppermost coil wires a and b in the A coil 31 and the B coil 32.

The power supply unit 34 is configured to supply DC power to the selected A coil 31 and B coil 32 based on a command of the controller 100 described below and form a magnetic field on an upper surface of a region in which the A coil 31 and B coil 32 supplied with power are arranged. For convenience of illustration, only the power supply unit 34 corresponding to one A coil 31 is illustrated in FIG. 7, but the semiconductor manufacturing apparatus 1 is provided with a plurality of power supply units 34 and is configured to be able to supply power to the driving coil 3 in units of one coil wire a and b, for example.

The tile unit T is configured to include a stack of the aforementioned A coil 31 and B coil 32 inside the container. Also, by arranging each tile unit T on the floor 151 of the housing 15, the A coil 31 and the B coil 32 provided on the adjacent tile units T are respectively connected, and the A coil 31 and the B coil 32 are arranged on the entire floor 151 of the housing 15.

In this manner, the transfer module 14 selects the A coil 31 and the B coil 32 located on the lower side of the region in which the magnet 4 of the moving body 2 is disposed and supplies DC power flowing in a predetermined direction. As a result, repulsive force is generated between the magnetic field formed by the driving coil 3 and the magnetic field of the magnet 4, and the main body portion 21 is moved by utilizing the repulsive force.

In this manner, the position in which the magnetic field is generated, the magnitude of magnetic force, and the direction of the magnetic field are adjusted in the A coil 31 and the B coil 32. Also, by controlling the magnetic field, the amount of levitation (levitation distance) of the main body portion 21 from the floor 151, the direction or movement direction of the main body portion 21 are adjusted. As a result, the main body portion 21 may be made to assume a desired posture on the floor 151 of the transfer module 14 and may also be moved in a desired direction.

At this time, a height position of the moving body 2 is set so that, for example, the transfer position for executing the transfer of the wafer W between the moving body 2 and the load lock module 13 or the processing module 11 is higher than the transfer position for moving within the transfer module 14. In this manner, when executing the transfer of the wafer W to the modules 11 and 13, the moving body 2 is raised and lowered.

In addition, as shown in FIG. 3, a plurality of Hall sensors (position detection sensors) 75 are provided on the tile unit T provided on the floor 151 of the housing 15, for example, below the stack of the driving coil 3. The Hall sensor 75 is an example of a magnetic sensor, is a sensor for detecting a position of the magnet 4 of the moving body 2, and is arranged in a matrix shape in the longitudinal and transverse directions on the front surface of the floor 151. Using the detection result by this Hall sensor 75, the controller 100 may detect the position and direction of the main body portion 21.

### <Controller>

The semiconductor manufacturing apparatus 1 is equipped with a controller 100. The controller 100 is configured by a computer having a CPU and a memory unit and controls each part of the semiconductor manufacturing apparatus 1. The memory unit records a program in which a group of steps (commands) for controlling the operation of the processing module 11 is organized. The program is stored in a storage medium, such as a hard disk, a compact disk, a magnet optical disk, a memory card, or a non-volatile memory, and is installed in the computer from there. In addition, the memory unit also stores a program for executing movement or power supply of the moving body 2.

An example of transferring the wafer W in the semiconductor manufacturing apparatus 1 is briefly described. The wafer W in the carrier C mounted on the load port 121 is transferred to the load lock module 13 in an atmospheric pressure atmosphere by the transfer mechanism 122. Then, after the inside of the load lock module 13 is switched from the atmospheric pressure atmosphere to a vacuum atmosphere, the wafer W in the load lock module 13 is transferred to the processing module 11 that performs processing of the wafer W by the moving body 2.

In the processing module 11, the wafer W mounted on the mounting table 111 is heated as needed to increase the temperature to a preset temperature, and at the same time, if a processing gas supply unit is provided, processing gas is supplied into the processing module 11. In this manner, desired processing for the wafer W is performed.

When the processing of the wafer W is performed, the wafer W is transferred in the reverse order of the loading, and the wafer W is returned from the processing module 11 to the load lock module 13. In addition, after the atmosphere of the load lock module 13 is switched to the atmospheric pressure atmosphere, the wafer W is returned to the predetermined carrier C by the transfer mechanism 122. In addition, the wafer W may be transferred to and processed by only one processing module 11 or may be transferred between a plurality of processing modules 11 and processed by each processing module 11.

As described above, the moving body 2 is levitated from the floor 151 by magnetic force and moves with a high degree of freedom within the transfer module 14. For this reason, in the transfer module 14, it is required to supply power to the power consuming device mounted on the moving body 2 without affecting the transfer operation of the moving body 2, and an inductive power supply using the first coil 5 and the second coil 6 is performed.

In the power supply, as described above, for example, AC power is constantly supplied to the first coil 5 from the power supply unit 54 through the DC/AC conversion circuit 53.

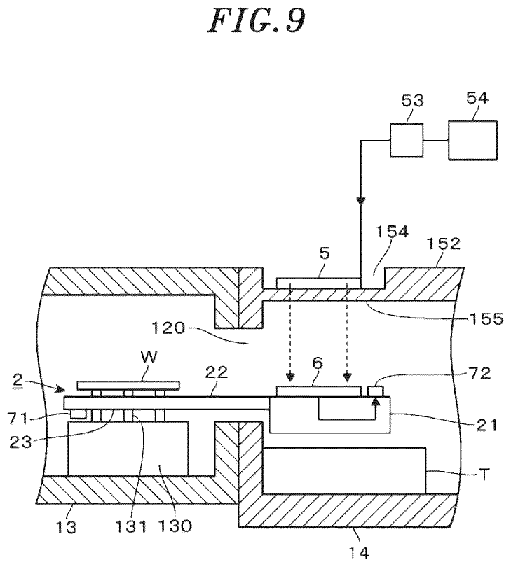

When transferring the wafer W between the load lock module 13 and the moving body 2, the moving body 2 moves to the transfer position facing the load lock module 13. FIG. 9 illustrates a state in which the wafer W is transferred between the moving body 2 at the transfer position and the load lock module 13.

When the moving body 2 receives the wafer W from the load lock module 13, the fork 22 of the moving body 2 moving to the transfer position dives below the wafer W supported by the lifting pin 131 to levitate from the stage 130. Then, the corresponding moving body 2 stops at the transfer position and becomes the state shown in FIG. 9, and the wafer W is mounted on the fork 22 by lowering the lifting pin 131.

Meanwhile, when sending the wafer W from the moving body 2 to the load lock module 13, the lifting pin 131 pushes up the wafer W with respect to the moving body 2 that has moved to the transfer position and stopped, and becomes the state shown in FIG. 9. Thereafter, the wafer W is loaded on the stage 130 by retracting the moving body 2 from the transfer position and the lowering the lifting pin 131.

As described above, the moving body 2 is located at the transfer position to perform the transfer of the wafer W between the moving body 2 and the load lock module 13, and the movement in the lateral direction stops. At that time, the first coil 5 provided in the housing 15 and the second coil 6 provided in the moving body 2 are in a state of facing each other. Therefore, as described in FIG. 8, an induced current is generated in the second coil 6, and the battery 72 is charged. The arrow indicated by the broken line in FIG. 9 indicates magnetic flux penetrating through the opening of the second coil 6 also illustrated in FIG. 8. In addition, at the transfer position, the moving body 2 may be raised and lowered.

According to the present embodiment, the driving coil 3 of the moving body 2 for moving the moving body 2 in a state in which the moving body 2 is levitated by magnetic force is installed on the floor 151 of the moving space S of the housing 15. While disposing the driving coil 3 in this manner, the first coil 5 for power supply corresponding to the second coil 6 for receiving power in the moving body 2 is provided above the moving space S of the moving body 2. For this reason, the processing module 11 may be disposed on the side of the moving space S without providing the coil for power supply, thereby enabling dense arrangement of a plurality of processing modules 11. That is, the installation of the first coil 5 for power supply is prevented from interfering with the installation of the processing module 11, and the wafer W may be processed in parallel with each of the plurality of installed processing modules 11, thereby increasing throughput of the device. In addition, there is no need to increase the occupied area of the device in order to dispose the first coil 5 by utilizing the upper region of the housing 15 in this manner.

In addition, when transferring the wafer W to perform processing in the semiconductor manufacturing apparatus 1, the first coil 5 is provided above a first region R1 in which the moving body 2 has a long dwell time (in the present embodiment, above the transfer position to the load lock module 13). Therefore, by utilizing the dwell time of the moving body 2 in the first region R1, an induced current may be generated in the second coil 6 to charge the battery 72 and secure power supplied to the power consuming device. Accordingly, there is no need to secure a time for supplying power to the power consuming device separately from the dwell time. That is, since charging may be performed by utilizing the time during the operation required for transferring the wafer W, power supplied to the power consuming device may be secured without reducing the transfer (throughput).

In addition, for the moving body 2, a configuration in which wireless charging is not performed as in the present embodiment by mounting a large-capacity battery that has been pre-charged or a configuration in which power is supplied to a power consuming device by a wire using a cable is considered. However, with these methods, there is a concern that the levitation of the moving body 2 may be hindered due to the weight of the battery or the movement of the moving body 2 may be restricted to prevent cable entanglement, so the present technology is useful for these configurations.

In the above, in the present embodiment, the first coil 5 may be disposed above the position right in front of the processing module 11 and power may be supplied to the moving body 2 when the wafer W is transferred to the processing module 11, so that the battery 72 may be charged. However, as described above, the moving body 2 of the wafer W frequently accesses the load lock module 13 for transferring the wafer W between the carrier C and the processing module 11. Therefore, when comparing the position right in front of the load lock module 13 with the position right in front of the processing module 11, the dwell time per unit time is longer at the position right in front of the load lock module 13.

The position right in front as referred to here is a position in which the moving body 2 stops moving to transfer the wafer W with respect to the load lock module 13 or the processing module 11 and is a position shown in FIG. 9 with respect to the load lock module 13. Also, the unit time is a relatively long time during the period from when the transfer module 14 starts operation to process the wafer W in the semiconductor manufacturing apparatus 1 to when the operation of the transfer module 14 terminates due to the stoppage of processing of the wafer W, for example, a time of 10 hours or more starting from any point in time for the corresponding period.

In this manner, since there is a difference in the dwell time per unit time, in the aforementioned embodiment, among the upper portion of the position right in front of the load lock module 13 and the upper portion of the position right in front of the processing module 11, the first coil 5 is provided limitedly in the upper portion of the position right in front of the load lock module 13 to secure sufficient charging time. By limiting the position in which the first coil 5 is provided to the upper portion right in front of a specific module, the increase in component parts is suppressed, thereby preventing an increase in the manufacturing cost of the transfer module 14.

However, the processing time of the wafer W in each of the processing modules 11 may be arbitrarily set. Depending on the setting of the processing time, the time from when the moving body 2 transfers the wafer W to the processing module 11 until it receives the wafer W is relatively long. In such a case, the first coil 5 may be provided above the processing module 11. Then, during the processing of the wafer W in the processing module 11, the second coil 6 of the moving body 2 may be disposed below the first coil 5 so that the battery 72 may be charged. The processing modules 11 are provided in plurality, and it is preferable to provide the power supply coil only in the upper portion near the processing module 11 in which the processing is performed for a long period of time as described above among the regions near each processing module 11. That is, in this case, the vicinity of the processing module 11 in which the processing is performed for a long period of time is the region R1 in which the dwell time per unit time is long, and the other region is a region R2 in which the dwell time per unit time is short, and the first coil 5 is provided above the region R1.

In addition, if the processing in the processing module 11 is performed for a long period of time and a waiting time of the moving body 2 in the vicinity of the corresponding processing module 11 may be made relatively long, there is no need to provide the first coil 5 right above the load lock module 13 described so far. That is, the first coil 5 is not limited to being provided at a position corresponding to the load lock module 13. In this case, the first coil 5 may be disposed above the position which is the first region R1 in which the dwell time is long, depending on the movement situation of the moving body 2 when viewed in the long term.

In addition, in the present embodiment, the first coil 5 does not need to be provided according to the number of load lock modules 13. The number of first coils 5 may be less than the number of load lock modules 13, for example, one, or more than the number of load lock modules 13. In many cases, the first coil 5 is provided above the transfer position with respect to the load lock module 13 and above the transfer position with respect to the processing module 11.

In addition, the first coil 5 may be provided at a position spaced upward from the ceiling wall 152 of the housing 15 or may be buried inside the ceiling wall 152.

In addition, in a case in which the first coil 5 is provided above the transfer position with respect to the processing module 11, if the power consuming device is a camera or sensor for detecting the state inside the corresponding processing module 11, the battery 72 may not need to be provided. The induced current obtained from the second coil 6 may be converted into DC power by, for example, the AC/DC conversion circuit 741, and then directly supplied to the power consuming device to detect the state within the processing module 11.

In addition, in the case of not detecting the state within the processing module 11 but detecting the state within the load lock module 13, the state within the corresponding module may be detected by supplying DC power obtained from the induced current of the second coil 6 by the operation of the first coil 5 at the position described in FIG. 2 or the like to the power consuming device without passing through the battery 72. That is, even in this case, the battery 72 may not be provided.

In addition, regarding the transfer of the wafer W by the moving body 2, the same moving body 2 is described as being transferred for the same wafer W, but the moving body 2 in use may be appropriately switched. That is, the transfer of the wafer W from one module to another module may be performed by one moving body 2, and the transfer of the wafer W from another module to another module may be performed by another moving body 2.

### Second Embodiment

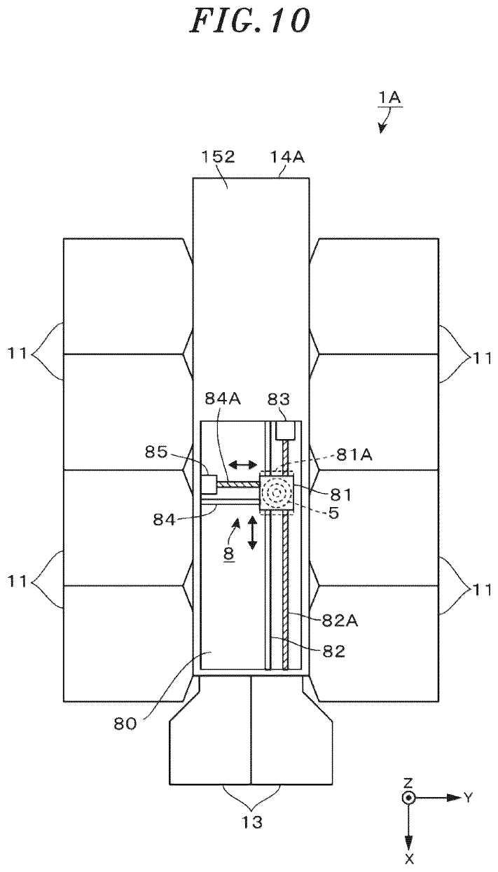

Subsequently, the second embodiment of the transfer module 14A of the present disclosure is described with reference to FIGS. 10 to 13. A difference between the present embodiment and the first embodiment is that a moving mechanism 8 is provided to move the first coil 5 according to the lateral (horizontal) movement of the moving body 2.

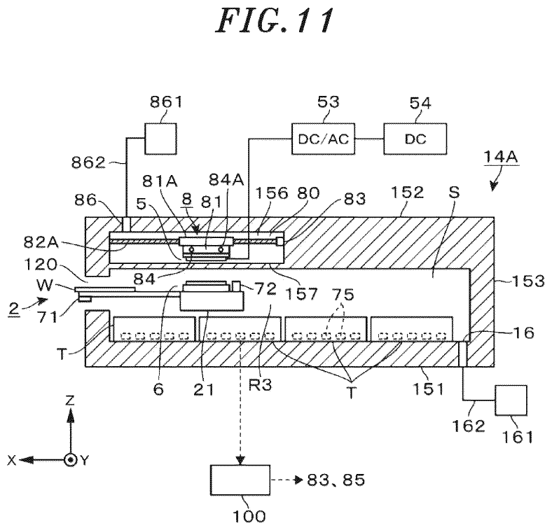

As shown in FIGS. 10 and 11, a power supply space 80 having the first coil 5 and the moving mechanism 8 of the first coil 5 is formed, for example, inside the ceiling wall 152 in a portion of the ceiling wall 152 of the housing 15 of the transfer module 14A.

In this example, a rectangular concave portion 156 is formed in a plane from the lower surface side of the ceiling wall 152, and the opening of this concave portion 156 is closed by a partition 157. A lower surface of the partition 157 is integrated with a lower surface of the ceiling wall 152 in a region in which the concave portion 156 is not formed, thereby forming the ceiling surface of the moving space S.

For example, a region in which the power supply space 80 is formed is, in this example, a region close to the load lock module 13 when the transfer module 14A is viewed on a plane. With respect to the moving space S, a region below the power supply space 80 is configured as a power supply region R3 for wirelessly supplying power with respect to the moving body 2.

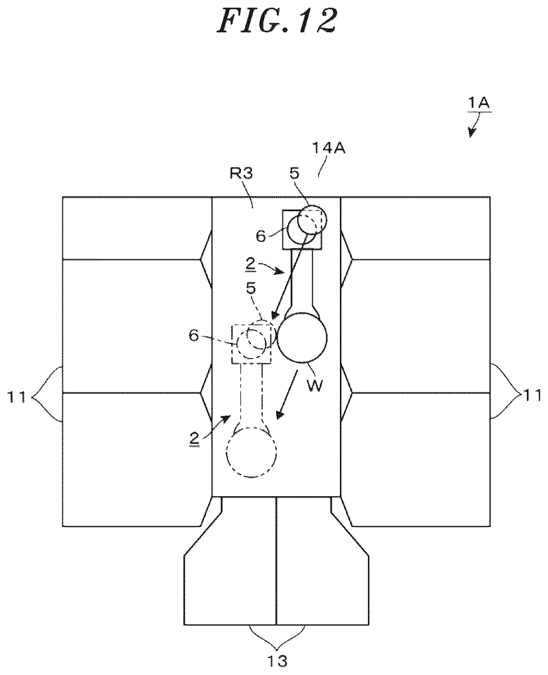

As described above, in the transfer of the wafer W in the transfer module 14, the operation of executing the transfer of the wafer W between the load lock module 13 and the moving body 2 is necessarily performed. Therefore, as shown in FIGS. 10 and 11, the power supply region R3 includes a transfer position for executing the transfer of the wafer W to the load lock module 13 and is formed, for example, on the front side of the transfer module 14 in the front-rear direction. In addition, as shown in FIG. 12, the power supply region R3 also includes a transfer position for executing the transfer of the wafer W between the moving body 2 and the processing module 11 located close to the load lock module 13.

The moving mechanism 8 provided inside the power supply space 80 includes, for example, a stage 81 configured in a rectangular shape when viewed on a plane and a support portion 81A which is an elongated member in the Y direction located above the corresponding stage 81. In addition, in FIG. 10, the support portion 81A is shown as the broken line, but the support portion 81A is not limited to this shape. The support portion 81A is connected to a guide rail 82 that extends in the X direction and a ball screw 82A that extends in the X direction in parallel with the guide rail 82. The support portion 81A moves in the X direction by rotating the ball screw 82A by a motor 83 for X-direction movement.

In this example, an upper surface of the stage 81 is connected to a lower surface of the support portion 81A, and the stage 81 is connected to a guide rail 84 that extends in the Y direction and a ball screw 84A that extends in the Y direction in parallel with the guide rail 84. The stage 81 moves in the Y direction by rotating the ball screw 84A by a motor 85 for Y-direction movement. In addition, according to the movement of the support portion 81A, the stage 81, the guide rail 84, the ball screw 84A, and the motor 85 provided on the corresponding stage 81 also move. Therefore, the stage 81 is configured to be movable in the X direction and the Y direction respectively by the motors 83 and 85.

These motors 83 and 85 are also provided inside the power supply space 80 and are configured to move the stage 81 to a predetermined position based on position information of the moving body 2 from the hall sensor 75 provided on the floor 151 of the housing 15.

The first coil 5 is provided on a lower surface of the stage 81. The first coil 5, as in the first embodiment, is configured by winding the coil wire 52 in a spiral shape when viewed on a plane on the base member 51 formed of an insulator. However, unlike the first embodiment, the coil wire 52 is provided on the stage 81 to face downward. A thickness of the partition 157 between the power supply space 80 and the moving space S is set to a size that does not interfere with electromagnetic induction by the moving mechanism 8 described below. In addition, an exhaust port 86 is formed in the power supply space 80 and is connected to an exhaust mechanism 861 equipped with a valve or a pump by an exhaust path 862 through the exhaust port 86. In this manner, the pressure inside the power supply space 80 is reduced to be equal to the pressure inside the moving space S by the exhaust mechanism 861.

In the second embodiment, the first coil 5 moves according to the lateral movement of the moving body 2. In this manner, the first coil 5 moves according to the movement of the moving body 2, but it is considered that a winding axis of the first coil 5 and a winding axis of the second coil 6 of the moving body 2 are slightly misaligned when viewed on a plane due to a response delay of the movement control of the first coil 5. That is, it is considered that the second coil 6 is misaligned from a region with the strongest magnetic field formed by the first coil 5. Therefore, in order to sufficiently secure the magnetic field intensity around the second coil 6, the thickness of the partition 157 is made relatively small. In this manner, although the partition 157 becomes thin, as described above, since the pressure of the power supply space 80 and the pressure of the moving space S are even by decompressing the power supply space 80, deformation of the partition 157 due to a pressure difference between these spaces is prevented.

In this manner, the reason for partitioning the power supply space 80 and the moving space S by the partition 157 is to suppress diffusion of particles that may occur due to movement toward the moving space S because the first coil 5 moves above the moving body 2 in the power supply space 80. In addition, these particles are removed by exhausting the power supply space 80, but the configuration in which the power supply space 80 is exhausted not only achieves the effect of removing these particles, but also contributes to increasing the power supply efficiency for the moving body 2 by suppressing the thickness of the partition 157, as described above.

In addition, the power supply space 80 may also be formed in an atmospheric atmosphere. In this case, as in the first embodiment, a concave portion is formed from the upper side in the ceiling wall 152, the first coil 5 and the moving mechanism 8 are provided in the concave portion, and the first coil 5 is configured to be horizontally movable by the moving mechanism 8.

In addition, the controller 100 of this example outputs a drive command to each of the motor 83 for X-direction movement and the motor 85 for Y-direction movement based on the detection result of the magnet 4 of the moving body 2 detected by the Hall sensor 75 and is configured to move the first coil 5 by following the second coil 6 of the moving body 2.

For example, the position of the magnet 4 of the main body portion 21 is detected by the Hall sensor 75, and the center position P when the main body portion 21 is viewed on a plane is acquired. Also, the positional relationship between the center position P of the main body portion 21 and a center position (a position of the winding axis) P2 of the second coil 6 when viewed on a plane is determined in advance, and a center position P2 of the second coil 6 is calculated based on the center position P. The controller 100 outputs a drive command to the motors 83 and 85 so that the center position P1 of the first coil 5 when viewed on a plane and the center position P2 of the second coil 6 are opposed.

In addition, the moving body 2 of this example includes a remaining capacity sensor (not shown) that detects the remaining capacity of the battery 72, and a detection value of the remaining capacity sensor is configured to be output to the controller 100 wirelessly via a transmitter of the moving body 2. Also, the controller 100 is configured to determine the remaining capacity of the battery 72 for each of the plurality of moving objects 2 and select the moving object 2 to be supplied with power first based on the remaining capacity. The other components of the transfer module 14A of the second embodiment are the same as those of the first embodiment, and the same reference numerals are given to the same components, and illustration is omitted.

In the present embodiment, AC power is constantly supplied to the first coil 5 through the power supply unit 54 and the DC/AC conversion circuit 53. Then, in the transfer module 14A, similarly to the first embodiment, the wafer W in the load lock module 13 is received from the moving body 2, transferred to the preset processing module 11, and delivered to the mounting table 111 of the processing module 11. Thereafter, the moving body 2 moves to the load lock module 13 and receives the next wafer W or moves to another processing module 11, receives the wafer W on which processing has been performed, and transfers the wafer W to the load lock module 13.

Also, as shown in the power supply region R3 in FIG. 12, for the moving body 2 moving in this region, position information of the second coil 6 is acquired by the detection result of the Hall sensor 75, and the first coil 5 is moved by the moving mechanism 8 according to the position of the second coil 6. In this manner, the first coil 5 is moved to face the second coil 6 in accordance with the movement of the moving body 2, and an induced current is generated in the second coil 6 by electromagnetic induction. In addition, in this drawing, in order to show the positional relationship between the first coil 5 and the second coil 6, the components other than the coils 5 and 6 are shown in a simplified manner.

In addition, since power is supplied by electromagnetic induction, high positional accuracy is not required in the positional relationship between the first coil 5 and the second coil 6. Since the second coil 6 enters the magnetic field formed by the first coil 5 and an induced current is generated, as shown in FIG. 12, the winding axes of the coils may be misaligned when viewed on a plane or only portions of the coils may be opposed.

The movement of the first coil 5 is initiated, for example, at a timing when the moving body 2 receives the wafer W from the load lock module 13. Then, the first coil 5 follows the second coil 6 of the moving body 2 moving within the power supply region R3 and supplies power, but when the moving body 2 being followed moves outside the power supply region R3, the second coil 6 of the moving body 2 that has entered the power supply region R3 is followed and supplies power. In this manner, the battery 72 is charged by the induced current generated in the second coil 6, and the power charged in the battery 72 is supplied to the sensor 71.

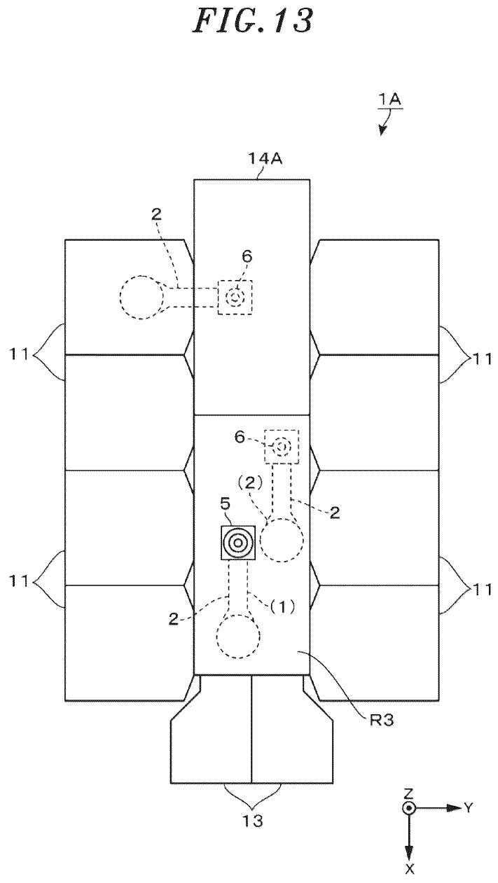

In addition, when a plurality of moving bodies 2 are within the power supply region R3, for example, as shown in FIG. 13, the priority of the moving body 2 that the first coil 5 follows and performs wireless power supply may be determined by the remaining capacity of the battery 72. In FIG. 13, as the priority, priorities 1 and 2 are given to the moving body 2. For example, the remaining capacity of the battery 72 is constantly detected by a remaining capacity detection sensor and output to the controller 100. Then, the controller 100 compares the remaining capacity of the batteries 72 of each moving body 2 within the power supply region R3 and selects the moving body 2 (1) with the smallest remaining capacity. Also, the controller outputs a command the first coil 5 to follow the second coil 6 of the moving body 2 (1).

The first coil 5 preferentially follows the corresponding moving body 2 (1) and supplies power until the corresponding moving body 2 (1) moves outside the power supply region R3 or until the wafer W is transferred to the processing module 11 accessible from the power supply region R3.

Subsequently, the controller 100 compares the remaining capacities of the battery 72 of each moving body 2 in the power supply region R3 again and selects the moving body 2 with the smallest remaining capacity. Also, the controller 100 outputs a command to the first coil 5 to follow the second coil 6 of the selected moving body 2.

Also, in the present embodiment, as in the first embodiment, the driving coil 3 of the moving body 2 is provided on the floor 151 of the housing 15, while the second coil 6 for receiving power is provided on the moving body 2 and the first coil 5 for power supply is provided above the moving space S of the moving body 2. Therefore, there is no need to install a coil on the side of the moving space S, and since a plurality of processing modules 11 may be densely arranged on the side, throughput of the device may increase.

In addition, since the first coil 5 is moved to follow the moving body 2 and an induced current is generated in the second coil 6, power may be supplied to a power consuming device while the moving body 2 is moving. For this reason, there is no need to secure a power supply time separately from the movement time of the moving body 2, so that power may be supplied to the power consuming device without lowering the transfer (throughput).

In the above, in the present embodiment, the region in which the power supply space 80 is provided is not limited to the aforementioned example and may be formed to correspond to a region including the transfer position of the wafer W between all the processing modules 11 and the moving body 2. That is, the power supply space 80 may be formed to cover the entire moving space S. In this case, since the first coil 5 constantly follows the moving body 2, the battery 72 does not need to be provided in the moving body 2. In this case, the induced current obtained from the second coil 6 may be converted into DC by, for example, the AC/DC conversion circuit 741, and then directly supplied to the power consuming device, and the state within the processing module 11 may be detected.

In addition, it is not necessary to use the detection result by the Hall sensor 75 for the movement of the first coil 5 according to the movement of the moving body 2. For example, a program that controls the operation of the motor 83 and 85 may be set in advance and installed in the controller 100 so that the moving body 2 moves as programmed according to the preset transfer path and the first coil 5 also moves along the transfer path within the transfer module 14A.

In the above, in the semiconductor manufacturing apparatus 1 of the present disclosure, as long as the first coil 5 and the second coil 6 may generate an induced current in the second coil 6 by electromagnetic induction, their shapes are not limited to the aforementioned examples. For example, the coil wires 52 and 62 may be configured to be wound in a circumferential direction along the sidewalls of the base members 51 and 61 and opened in the up-down direction.

In addition, the driving coil 3 may have a different configuration as long as it may move the moving body 2 equipped with the magnet 4 in a state of being levitated from the floor by magnetic force. For example, a coil wound in a spiral shape may be arranged around a vertical axis.

In addition, in the first embodiment and the second embodiment, if the remaining capacity of the battery 72 is sufficient, it is not necessary to perform wireless power supply in the second coil 6. In this case, in the first embodiment, the power supply to the first coil 5 may be stopped, and in the second embodiment, the following of the moving body 2 by the first coil 5 may be stopped.

In addition, as a power consuming device provided in the moving body 2, in addition to various sensors, cameras, and lights as described above, if the magnet provided in the main body portion 21 is an electromagnet, the electromagnet may also be exemplified.

In addition, in the semiconductor manufacturing apparatus 1 of the present disclosure, the processing module 11 is not limited to a module that processes the wafer W in a vacuum atmosphere and may be configured to perform processing of the wafer under an atmospheric pressure atmosphere. In this case, the transfer modules 14 and 14A may be set to an atmospheric pressure atmosphere.

So far, in the transfer module 14, it is described that the wafer W is transferred as a substrate, but the transferred substrate is a semiconductor manufacturing substrate or a flat panel display manufacturing substrate. In addition to the wafer W, the semiconductor manufacturing substrate includes a substrate used in a semiconductor manufacturing process. A substrate for manufacturing a flat panel display (FPD) includes various FPDs, such as a liquid crystal display, a plasma display, an organic EL display, a field emission display, or electronic paper, and a substrate used in a manufacturing process of the FPD. The substrate used in the semiconductor manufacturing process, the substrate used in the FPD manufacturing process, includes a substrate that is a photomask used for exposure processing during each manufacturing process, and a dummy substrate that is processed for the purpose of testing or setting processing parameters in a substrate processing device.

The disclosed embodiment should be considered as illustrative and not restrictive in all respects. The embodiment may be omitted, substituted, or modified in various forms without departing from the scope of the appended claims and their gist.

1. A transfer module used in a semiconductor manufacturing apparatus, in which a moving body equipped with a magnet moves in a state of being levitated from a floor by magnetic force to transfer a substrate to a processing module for processing the substrate, the transfer module comprising:
the moving body;
a housing forming a moving space therein where the moving body moves;
a power consuming device provided in the moving body;
a first coil provided above the moving space; and
a second coil provided in the moving body to generate an induced current through a magnetic field formed by the first coil, which is powered, in order to supply power to the power consuming device.

2. The transfer module of claim 1, wherein the moving body includes a battery which is configured to supply power to the power consuming device, and charging of the battery is performed by the induced current.

3. The transfer module of claim 2, wherein the moving space has a first region and a second region, where the positions in a lateral direction are different and dwell times of the moving body per unit time are different, and
the first coil is provided limitedly above the first region, where the dwell time is longer than in the second region.

4. The transfer module of claim 2, wherein
the housing includes:
an exhaust port exhausting the moving space to form a vacuum atmosphere;
a first transfer port which is configured to be opened to transfer the substrate between the transfer module and the processing module which is connected from a side of the housing and is configured to process the substrate in the vacuum atmosphere, the first transfer port being opened and closed by a first valve; and
a second transfer port which is opened and closed by a second valve and is configured to transfer the substrate between the transfer module and a load lock module, which is connected from the side of the housing and where the atmosphere switches between vacuum and atmospheric pressure,
wherein the first coil is provided above a position where a lateral movement of the moving body stops in order to transfer the substrate to the load lock module.

5. The transfer module of claim 3, wherein
the housing includes:
an exhaust port exhausting the moving space to form a vacuum atmosphere;
a first transfer port which is configured to be opened to transfer the substrate between the transfer module and the processing module which is connected from a side of the housing and is configured to process the substrate in the vacuum atmosphere, the first transfer port being opened and closed by a first valve; and
a second transfer port which is opened and closed by a second valve and is configured to transfer the substrate between the transfer module and a load lock module, which is connected from the side of the housing and where the atmosphere switches between vacuum and atmospheric pressure,
wherein the first coil is provided above a position where a lateral movement of the moving body stops in order to transfer the substrate to the load lock module.

6. The transfer module of claim 1, wherein a moving mechanism is provided to move the first coil in a lateral direction according to a lateral movement of the moving body.

7. The transfer module of claim 6, wherein a plurality of Hall sensors for detecting a position of the magnet are provided on the floor, and
the first coil moves based on a detection result from the Hall sensors.

8. The transfer module of claim 1, wherein the housing is provided with a first transfer port which is configured to be opened to transfer the substrate between the transfer module and the processing module which is connected from a side of the housing and is configured to process the substrate, the first transfer port being opened and closed by a first valve, and
the power consuming device is a sensor located within the processing module and detecting a state within the processing module, when the substrate is transferred between the processing module and the moving body.

9. A substrate transfer method in a semiconductor manufacturing apparatus, the substrate transfer method comprising:
a process of moving a moving body equipped with a magnet in a state of being levitated from a floor by magnetic force within a moving space formed inside a housing,
a process of transferring a substrate to a processing module for processing the substrate by the moving body,
a process of supplying power to a first coil provided above the moving space and generating an induced current in a second coil provided in the moving body through a magnetic field formed by the first coil, in order to supply power to a power consuming device provided in the moving body.
